(19) United States
(12) Patent Application Publication
(10) Pub. No.: US 2022/0045302 A1
(43) Pub. Date: Feb. 10, 2022

(54) DISPLAY DEVICE AND ORGANIC LIGHT-EMITTING DIODE PANEL THEREOF, AND METHOD FOR MANUFACTURING ORGANIC LIGHT-EMITTING DIODE PANEL

(71) Applicant: BOE Technology Group Co., Ltd., Beijing (CN)

(72) Inventors: Pan XU, Beijing (CN); Yicheng LIN, Beijing (CN); Ling WANG, Beijing (CN); Guoying WANG, Beijing (CN); Xing ZHANG, Beijing (CN); Ying HAN, Beijing (CN)

(21) Appl. No.: 17/416,497

(22) PCT Filed: Nov. 25, 2020
(86) PCT No.: PCT/CN2020/131411

§ 371 Date: Jun. 20, 2021

(30) Foreign Application Priority Data
Nov. 29, 2019 (CN) 201911201429.6

(51) Int. Cl. H01L 51/52; H01L 27/32; H01L 51/56

(52) U.S. Cl. CPC H01L 51/5253; H01L 27/3276; H01L 2227/323; H01L 51/56; H01L 51/5284

(57) ABSTRACT

The present disclosure provides a display device and an OLED panel thereof, and a method for manufacturing an OLED panel. The OLED panel includes: a substrate (10), and a light-emitting structure (11) disposed on the substrate (10), wherein at least one film layer (12) and a planarization layer disposed on the at least one film layer (12) are disposed between the substrate (10) and the light-emitting structure (11); the OLED panel comprises a first region (12a) and a second region (12b), wherein a source (124a) and a drain (124b) of the transistor are disposed in the first region (12a); wherein the at least one film layer (12) comprises an insulating layer, wherein a thickness of the insulating layer in the first region (12a) is less than a thickness of the insulating layer in the second region (12b). According to the embodiments of the present disclosure, the global flatness of the at least one film layer is improved, thereby improving the planarization effect of the planarization layer, and further improving the quality of the organic light-emitting layer and the brightness uniformity of the sub-pixels.

This application claims priority to the Chinese Patent Application No. 201911201429.6, filed on Nov. 29, 2019 and entitled “DISPLAY DEVICE AND OLED PANEL THEREOF, AND METHOD FOR MANUFACTURING OLED PANEL”, the entire content of which is incorporated herein by reference.

### TECHNICAL FIELD

The present disclosure relates to the technical field of display devices, and in particular, to a display device and an OLED panel thereof, and a method for manufacturing an OLED panel.

### BACKGROUND

Top-emission organic light-emitting diode (OLED) display technology has the advantages of long life, high pixels per inch (PPI), and the like, and has become the mainstream direction of the OLED industry. Whether for a small and medium-sized mobile phone screen that has been commercialized, or for a large-sized TV under technology research and development, top emission is an extremely advantageous technical direction for OLED panels.

### SUMMARY

The present disclosure provides a display device and an OLED panel thereof, and a method for manufacturing an OLED panel.

According to an aspect of the embodiments of the present disclosure, an OLED panel is provided. The OLED panel includes:

a substrate, and a light-emitting structure disposed on the substrate; wherein

at least one film layer and a planarization layer disposed on the at least one film layer are disposed between the substrate and the light-emitting structure, the at least one film layer includes a transistor;

the OLED panel includes a first region and a second region, wherein a source and a drain of the transistor are disposed in the first region; and

wherein the at least one film layer includes an insulating layer, wherein a thickness of the insulating layer in the first region is less than a thickness of the insulating layer in the second region.

In the present disclosure, the at least one film layer refers to a set of a plurality of film layers; the thickness of the insulating layer refers to a height difference between a bottom surface and a top surface of the insulating layer at a flat place, that is, its own thickness.

Optionally, the insulating layer includes an interlayer dielectric layer and/or a passivation layer.

Optionally, along a direction facing away from the substrate, the at least one film layer sequentially includes: a bottom gate, a gate insulating layer, an active layer, the interlayer dielectric layer, the source, the drain, and the passivation layer.

Optionally, the interlayer dielectric layer and/or the passivation layer is disposed only in the second region.

Optionally, a thickness of the interlayer dielectric layer in the first region is less than a thickness of the interlayer dielectric layer in the second region, and/or a thickness of the passivation layer in the first region is less than a thickness of the passivation layer in the second region.

Optionally, along the direction facing away from the substrate, the at least one film layer sequentially includes: an active layer, a gate insulating layer, a top gate, the interlayer dielectric layer, the source, the drain, and the passivation layer.

Optionally, the interlayer dielectric layer and/or the passivation layer is only disposed in the second region.

Optionally, the thickness of the interlayer dielectric layer in the first region is less than the thickness of the interlayer dielectric layer in the second region, and/or the thickness of the passivation layer in the first region is less than the thickness of the passivation layer in the second region.

Optionally, the at least one film layer includes at least two transistors, and the first region further includes a region where a connecting line between two of the at least two transistors is disposed.

Optionally, the at least one film layer include pixel drive circuits configured to drive the light-emitting structure to emit light, and/or the at least one film layer include connecting lines connecting the pixel drive circuits.

Optionally, the at least one film layer includes a light shielding layer.

Optionally, the first region includes N sub-regions, the second region includes M sub-regions, N+M≥3, and the thickness of the insulating layer in any two of the N+M sub-regions is different.

Optionally, along the direction facing away from the substrate, the at least one film layer sequentially includes: a bottom gate, a gate insulating layer, an active layer, the interlayer dielectric layer, the source, the drain, and the passivation layer;

the at least one film layer includes at least two transistors, and the first region further includes a region where a connecting line between two of the at least two transistors is disposed;

the at least one film layer includes pixel drive circuits configured to drive the light-emitting structure to emit light, and/or the at least one film layer includes connecting lines connecting the pixel drive circuits;

the at least one film layer includes a light shielding layer; and

the first region includes N sub-regions, the second region includes M sub-regions, N+M≥3, and the thickness of the insulating layer in any two of the N+M sub-regions is different.

According to another aspect of the present disclosure, a display device is provided. The display device includes any one of the above OLED panels.

According to another aspect of the present disclosure, a method for manufacturing an OLED panel is provided. The method includes:

providing a substrate;

forming at least one film layer on the substrate, wherein the at least one film layer includes a transistor, the OLED panel includes a first region and a second region, a source and a drain of the transistor being disposed in the first region, and the at least one film layer includes an insulating layer, wherein a thickness of the insulating layer in the first region is less than a thickness of the insulating layer in the second region;

forming a planarization layer on the at least one film layer; and

forming a light-emitting structure on the planarization layer.

In the present disclosure, a thickness of a certain film layer at a certain place refers to a height difference between a bottom surface of the film layer at that place and a top surface of the film layer at that place.

Optionally, the insulating layer includes an interlayer dielectric layer, and forming the at least one film layer on the substrate includes:

sequentially forming a bottom gate, a gate insulating layer, an active layer, and the interlayer dielectric layer on the substrate;

removing or thinning the interlayer dielectric layer in the first region, and forming, in the interlayer dielectric layer, through holes exposing a source region and a drain region; and

filling the through holes with a conductive material, and forming a source and a drain on the interlayer dielectric layer.

Optionally, the insulating layer includes an interlayer dielectric layer, and forming the at least one film layer on the substrate includes:

sequentially forming an active layer, a gate insulating layer, a top gate, and the interlayer dielectric layer on the substrate;

removing or thinning the interlayer dielectric layer in the first region, and forming, in the interlayer dielectric layer and the gate insulating layer, through holes exposing a source region and a drain region; and

filling the through holes with a conductive material, and forming a source and a drain on the interlayer dielectric layer.

Optionally, the insulating layer further includes a passivation layer, and forming the at least one film layer on the substrate further includes:

forming the passivation layer on the source, the drain and the interlayer dielectric layer; and

removing or thinning the passivation layer in the first region.

Optionally, the insulating layer includes a passivation layer, and forming the at least one film layer on the substrate includes:

sequentially forming a bottom gate, a gate insulating layer, an active layer, and an interlayer dielectric layer on the substrate;

forming, in the interlayer dielectric layer, through holes exposing a source region and a drain region;

filling the through holes with a conductive material, and forming a source and a drain on the interlayer dielectric layer;

forming the passivation layer on the source, the drain and the interlayer dielectric layer; and

removing or thinning the passivation layer in the first region;

or, forming the at least one film layer on the substrate includes:

sequentially forming an active layer, a gate insulating layer, a top gate, and an interlayer dielectric layer on the substrate;

forming, in the interlayer dielectric layer and the gate insulating layer, through holes exposing a source region and a drain region;

filling the through holes with a conductive material, and forming a source and a drain on the interlayer dielectric layer;

forming the passivation layer on the source, the drain and the interlayer dielectric layer; and

removing or thinning the passivation layer in the first region.

Optionally, the first region includes: a first sub-region, and sub-regions from a second sub-region to an N^{th} sub-region, and the second region includes: an (N+1)^{th} sub-region, and sub-regions from an (N+2)^{th} sub-region to an (N+M)^{th} sub-region, N+M≥3; wherein the first sub-region is a region where a level difference is greater than a first predetermined level difference, the second sub-region is a region where the level difference is greater than a second predetermined level difference and less than or equal to the first predetermined level difference, the third sub-region is a region where the level difference is greater than a third predetermined level difference and less than or equal to the second predetermined level difference, and the (N+M)^{th} sub-region is a region where the level difference is greater than an (N+M)^{th} predetermined level difference and less than or equal to an (N+M−1)^{th} predetermined level difference, wherein the first predetermined level difference, and the second predetermined level difference to the (N+M)^{th} predetermined level difference gradually decrease, and forming the at least one film layer on the substrate includes:

processing the insulating layer with a semi-transparent mask plate to completely remove the insulating layer in the first sub-region, and remove part of the thickness of the insulating layer in the second sub-region, the third sub-region to the (N+M)^{th} sub-region, wherein the thickness of the insulating layer removed from the second sub-region, the third sub-region to the (N+M)^{th} sub-region gradually decreases.

### BRIEF DESCRIPTION OF THE DRAWINGS

The drawings herein are incorporated into the description and constitute a part of the description, show embodiments that conform to the present disclosure, and are used together with the description to explain the principle of the present disclosure.

FIG. 1 is a top view of an OLED panel according to an embodiment of the present disclosure;

FIGS. 2 and 3 are two sectional views of FIG. 1;

FIG. 4 is a circuit diagram of a pixel drive circuit with a 2T1C structure;

FIG. 5 is a flowchart of a method for manufacturing an OLED panel according to an embodiment of the present disclosure;

FIGS. 6 and 7 are schematic diagrams of intermediate structures corresponding to the flow of FIG. 5;

FIG. 8 is a schematic sectional structure diagram of another OLED panel according to an embodiment of the present disclosure; and

FIG. 9 is a schematic sectional structure diagram of another OLED panel according to an embodiment of the present disclosure.

### LIST OF REFERENCE NUMERALS

| | |
|---|---|
| OLED panel 1, 2, 3 | Substrate 10 |
| Light-emitting structure 11 | At least one film layer 12 |
| At least one preset film layer 12′ | Level difference D |
| First region 12a | Second region 12b |
| Predetermined level difference D_{d} | Planarization layer PLN |
| First electrode 11a | Pixel definition layer PDL |
| Light-emitting structure block 11b | Second electrode 11c |
| Switch transistor X1 | Drive transistor X2 |
| Storage capacitor Cst | Scanning signal Sn |
| Data signal VData | Power signal VDD |
| Scanning signal line 20 | Data signal line 30 |
| Power signal line 40 | Bottom gate121 |
| Gate insulating layer 122 | Active layer 123 |
| Interlayer dielectric layer ILD | Source 124a |
| Drain 124b | Passivation layer PVX |
| Conductive plug 125a | Metal interconnection layer 125b |
| Maximum predetermined level | First predetermined level |
| difference Dₘₐₓ | difference D₁ |
| Second predetermined level | Third predetermined level |
| difference D₂ | difference D₃ |
| First sub-region 12c₁ | Second sub-region 12c₂ |
| Third sub-region 12c₃ | |

### DETAILED DESCRIPTION

Here, exemplary embodiments will be described in detail, and examples thereof are shown in the accompanying drawings. When the following description refers to the drawings, unless otherwise indicated, the same numbers in different drawings indicate the same or similar elements. The implementations described in the following exemplary embodiments do not represent all implementations consistent with the present disclosure. On the contrary, they are merely examples of devices and methods consistent with some aspects of the present disclosure as detailed in the appended claims.

Top-emission OLED display technology requires the substrate of the OLED panel to have a higher flatness, otherwise the optical characteristics of the OLED light-emitting structure will be affected, such as color cast, or even partial brightness. For small sizes, since the film layer of the back panel is relatively thin, the use of a general flat film can meet the flatness requirements of the OLED panel. However, for large or super-large sizes, the metal wires need very small resistance. That is, a very thick film layer is required. In this way, overlapping of a plurality of layers of metal conductors in the pixel circuit part will cause a higher level difference, and the use of ordinary flat films cannot meet the flatness requirements of OLED panels.

In the embodiments of the present disclosure, the thickness of a certain film layer structure (which may include one or more film layers) in a certain region may refer to a distance (or height difference) between a top surface and a bottom surface of the film layer structure in this region.

The level difference of a certain film layer structure in a certain region may refer to a thickness difference between the region and the thinnest part of the film layer structure. For example, the level difference of a certain film structure in region A may refer to a difference between the thickness of the film structure in region A and the thickness of the thinnest part of the film.

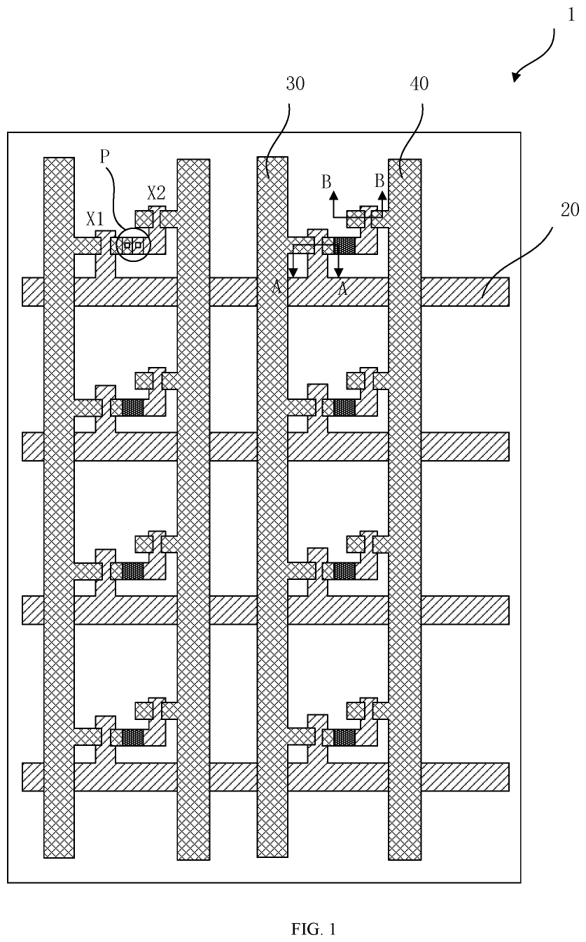

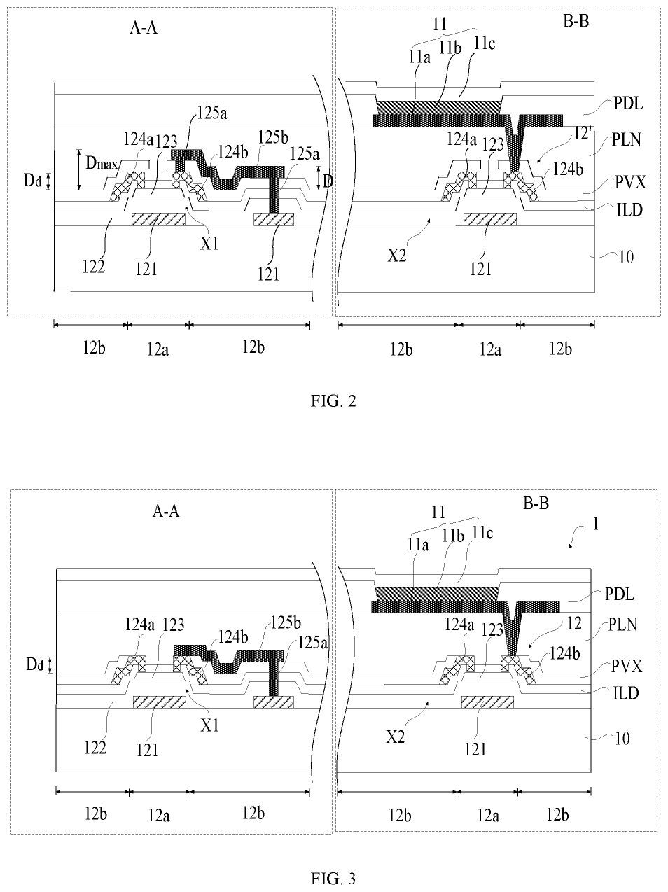

FIG. 1 is a top view of an OLED panel according to an embodiment of the present disclosure, in which a metal interconnection layer is not shown in a region P. FIG. 2 is a sectional view of line AA and line BB in the OLED panel shown in FIG. 1. FIG. 3 is another sectional view of line AA and line BB in the OLED panel shown in FIG. 1. In FIG. 2, a thickness of an insulating layer is the same everywhere. In FIG. 3, the thickness of the insulating layer is different in a first region 12a and a second region 12b.

Referring to FIGS. 1 to 3, the OLED panel 1 includes:

a substrate 10 and a light-emitting structure 11 disposed on the substrate 10. At least one film layer 12 and a planarization layer PLN disposed on the at least one film layer 12 are disposed between the substrate 10 and the light-emitting structure 11. The at least one film layer 12 may include a transistor. The OLED panel 1 includes the first region 12a and the second region 12b. The first region 12a includes at least a region where a source 124a and a drain 124b of the transistor are disposed (that is, the source and drain of the transistor are disposed in the first region). The at least one film layer 12 includes an insulating layer. A thickness of the insulating layer in the first region 12a is less than a thickness of the insulating layer in the second region 12b.

The second region 12b may be a region other than the first region 12a.

In summary, in the OLED panel according to the embodiment of the present disclosure, the thickness of the insulating layer in the first region is less than the thickness in the second region, improving the global flatness of the at least one film layer, which thus improves the flatness of the planarization layer and then improves the quality of the organic light-emitting layer and the brightness uniformity of the sub-pixels.

Referring to FIGS. 2 and 3, the substrate 10 may be a flexible substrate or a rigid substrate. The material of the flexible substrate may include polyimide, and the material of the rigid substrate may include glass.

A first electrode 11a is disposed on the planarization layer PLN. A pixel definition layer PDL is disposed on the first electrode 11a and the planarization layer PLN that does not cover the first electrode 11a. The pixel definition layer PDL has an opening exposing a partial region of the first electrode 11a. A light-emitting structure block 11b is disposed in the opening. A second electrode 11c is disposed on the light-emitting structure block 11b and the pixel definition layer PDL. The light-emitting structure block 11b may be a red light-emitting structure block, a green light-emitting structure block, or a blue light-emitting structure block, or may be a red light-emitting structure block, a green light-emitting structure block, a blue light-emitting structure block, or a yellow light-emitting structure block. The light-emitting structure blocks 11b of the three primary colors of red, green and blue or the four primary colors of red, green, blue and yellow are alternately distributed. The light-emitting structure block 11b may include an organic light-emitting material layer (OLED). The first electrode 11a may be an anode, and the material thereof is a reflective material. The second electrode 11c may be a cathode, and the material thereof is a material with a function of partially transmitting light and partially reflecting light. In other words, the OLED panel 1 may be a panel with a top emission structure.

In the embodiments of the present disclosure, the at least one film layer may include pixel drive circuits configured to drive the light-emitting structure to emit light, and/or the at least one film layer includes connecting lines connecting the pixel drive circuits.

Referring to FIGS. 1 to 3, in this embodiment, a pixel drive circuit is disposed between the first electrode 11a and the substrate 10. In other words, the light-emitting structure 11 is an active matrix OLED (AMOLED).

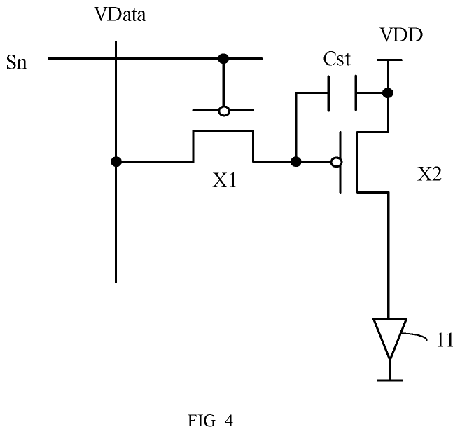

FIG. 4 is a circuit diagram of a pixel drive circuit with a 2T1C structure (a structure of the pixel drive circuit, which may include two thin-film transistors (TFT) and one capacitor storing charges, similarly a 7T1C structure also exists). Referring to FIG. 4, the pixel drive circuit includes a switch transistor X1, a drive transistor X2, and a storage capacitor Cst.

A gate of the switch transistor X1 is electrically connected to a row of scanning signal lines. When the row scanning signal Sn is at a turn-on voltage, the switch transistor X1 holds a data signal VData on a column of data signal lines on a plate of the storage capacitor Cst. When the scanning signal Sn is at a turn-off voltage, the data signal held on the storage capacitor Cst keeps the drive transistor X2 turned on, such that a power signal VDD on a column of power signal lines continuously supplies power to the first electrode 11a of the light-emitting structure 11.

Referring to FIGS. 1 and 4, the pixel drive circuits of the light-emitting structures disposed in the same row are connected to the same row of scanning signal lines 20, and the pixel drive circuits of the same color light-emitting structures disposed in the same column are connected to the same column of data signal lines 30 and the same column of power signal lines 40. The storage capacitor Cst may be formed by a region where the power signal line 40 overlaps the gate of the drive transistor X2.

Referring to FIGS. 2 and 3, in this embodiment, along a direction facing away from the substrate 10, the switch transistor X1 and the drive transistor X2 in the pixel drive circuit include a bottom gate 121, a gate insulating layer 122, an active layer 123, an interlayer dielectric layer ILD, the source 124a, the drain 124b, and a passivation layer PVX. The drain 124b of the switch transistor X1 and the bottom gate 121 of the drive transistor X2 are connected by a conductive plug 125a (two squares in the region P of FIG. 1 are the two conductive plugs 125a on the drain 124b and the bottom gate 121) and a metal interconnection layer 125b. The layers in the switch transistor X1 may be disposed on the same layer as the same functional layer in the drive transistor X2. The rows of scanning signal lines 20 may be disposed on the same layer as the bottom gate 121. The columns of data signal lines 30 and the columns of power signal lines 40 may be disposed on the same layer as the source 124a and the drain 124b.

Referring to FIG. 2, the thickness of the insulating layer is the same everywhere, and the various film layers of the pixel drive circuits and the connecting lines (including the scanning signal lines 20, the data signal lines 30, and the power signal lines 40) connecting the pixel drive circuits form at least one preset film layer 12′. An upper surface of the at least one preset film layer 12′ fluctuates in height. The thinnest part of the at least one preset film layer 12′, that is, the part with the smallest thickness includes: the gate insulating layer 122, the interlayer dielectric layer ILD, and the passivation layer PVX; the thickest part includes: the bottom gate 121, the gate insulating layer 122, the active layer 123, the interlayer dielectric layer ILD, the source 124a (or the drain 124b), the passivation layer PVX, and the metal interconnection layer 125b. A thickness difference between the thickest part and the thinnest part is the maximum predetermined level difference Dₘₐₓ. When the thicknesses of the metal layers, such as the bottom gate 121, the source 124a (or the drain 124b), and the metal interconnection layer 125b are relatively large, the maximum level difference Dₘₐₓ is relatively large. When the above level difference is planarized with the planarization layer PLN, the viscous property of the organic material of the planarization layer PLN will cause a poor planarization effect. If vapor deposition or inkjet printing of the light-emitting structure blocks 11b is continued on the plane with a poor planarization effect, the thickness of the light-emitting structure block 11b in some regions will be thick, and in other regions will be thin, causing uneven brightness or even no brightness during light emission of the light-emitting structural block 11b.

Based on the above analysis, in this embodiment, the at least one preset film layer 12′ is divided into the first region 12a and the second region 12b. The first region 12a is a region where the level difference D is greater than a predetermined level difference D_{d}. The second region 12b is a region where the level difference D is less than or equal to the predetermined level difference D_{d}. The first region 12a may include at least regions where the source 124a and the drain 124b of the transistor are disposed. The passivation layer PVX in the first region 12a is removed, that is, the thickness of the passivation layer PVX in the first region 12a is 0. Referring to FIG. 3, the at least one film layer 12 is obtained. The global flatness of the at least one film layer 12 is greater than the global flatness of the at least one preset film layer 12′, which can improve the planarization effect of the planarization layer PLN, improve the thickness uniformity of the light-emitting structure blocks 11b, and thereby improve the brightness uniformity.

The predetermined level difference D_{d} may be a predetermined proportion of the maximum predetermined level difference Dₘₐₓ, for example, 30%, 40%, 50%, 60%, 70%, or 80%. When the proportion value is different, the level difference ranges of the first region 12a and the second region 12b are different.

In this embodiment, the second region 12b includes at least a region where only the gate insulating layer 122, the interlayer dielectric layer ILD, and the passivation layer PVX are disposed.

The thickness of the at least one film layer 12 at a certain place refers to a height difference of the certain place between a bottom surface of the lowermost film layer and a top surface of the uppermost film layer in a set of a plurality of film layers, that is, the thickness of the plurality of film layers at the certain place. The thinnest part of the at least one preset film layer 12′ corresponds to the thinnest part of the at least one film layer 12. In other embodiments, the second region 12b may include at least the thinnest part of the at least one film layer 12.

In some embodiments, part of the thickness of the passivation layer PVX in the first region 12a may also be removed. That is, the passivation layer PVX in the first region 12a is thinned to obtain the at least one film layer 12.

In some embodiments, the at least one film layer 12 may also form a transistor other than the pixel drive circuit.

In some embodiments, the first region 12a may also include a region where a connecting line connecting two transistors is disposed. The connecting line may be a gate trace that connects a plurality of transistors, or connects the bottom gate 121 of one transistor (e.g., the drive transistor X2) and the drain 124b of another transistor (e.g., the switch transistor X1), or connects the source 124a of one transistor and the drain 124b of another transistor.

In some embodiments, the first region 12a may also include an overlapping region of two or more connecting lines, such as an overlapping region of the scanning signal lines 20 and the data signal lines 30, and an overlapping region of the scanning signal lines 20 and the power signal lines 40.

In some embodiments, the light-emitting structure 11 may also be a passive matrix OLED (PMOLED). The at least one preset film layer 12′ includes anode lines, cathode lines, an insulating layer that electrically insulates the anode lines and the cathode lines, and transistors. Removing or thinning the insulating layer in the first region 12a can improve the global flatness of the preset film layers 12′.

In some embodiments, the at least one film layer 12 further includes a buffer layer disposed on the substrate 10, and the material thereof may be silicon dioxide, silicon nitride, silicon oxynitride, or the like.

In some embodiments, along the direction facing away from the substrate 10, the switch transistor X1 and the drive transistor X2 may further include the active layer 123, the gate insulating layer 122, a top gate (not shown), the interlayer dielectric layer ILD, the source 124a, the drain 124b, and the passivation layer PVX. In these embodiments, when external light enters the OLED panel 1 from the bottom of the substrate 10, it will cause the channel of the switch transistor X1 and/or the drive transistor X2 to generate photo-generated carriers and change the threshold voltage. The at least one film layer 12 also includes a light shielding layer disposed between the substrate 10 and the active layer 123, thereby preventing the occurrence of the above problems. The light shielding layer may be disposed on the entire surface, or only under the active layer 123. For the switch transistor X1 and the drive transistor X2 with a bottom gate structure, if the size of the bottom gate 121 is less than the size of the active layer 123, a light shielding layer may also be disposed between the substrate 10 and the bottom gate 121.

In some embodiments, one of the switch transistor X1 and the drive transistor X2 may also have a top gate structure, and the other may have a bottom gate structure.

In some embodiments, the pixel drive circuit may also have a 7T1C structure or other structures, which is not limited in this embodiment.

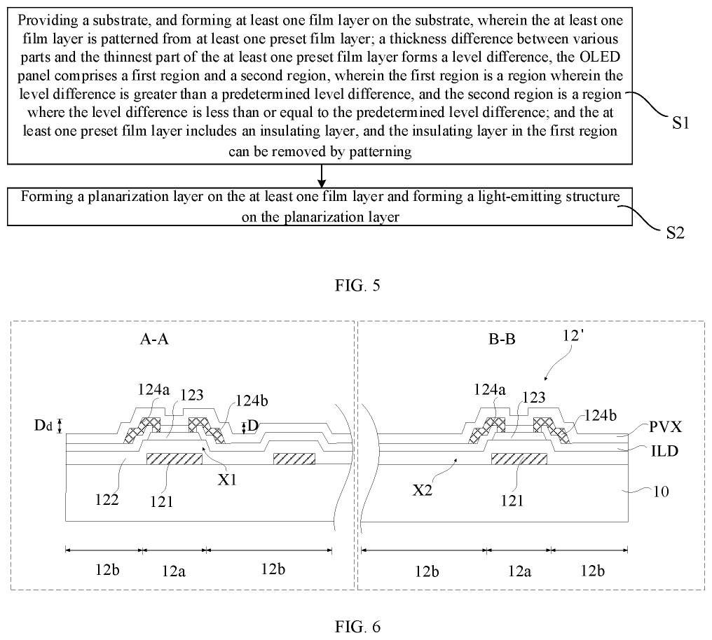

FIG. 5 is a flowchart of a method for manufacturing an OLED panel according to an embodiment of the present disclosure. FIGS. 6 and 7 are schematic diagrams of intermediate structures corresponding to the flow in FIG. 5.

First, referring to step S1 in FIG. 5, FIG. 6 and FIG. 7, a substrate 10 is provided, and at least one film layer 12 is formed on the substrate 10. The at least one film layer 12 is patterned from at least one preset film layer 12′. A thickness difference between various parts and the thinnest part of the at least one preset film layer 12′ forms a level difference D. The OLED panel has a first region 12a and a second region 12b. The first region 12a is a region where the level difference D is greater than a predetermined level difference D_{d}. The second region 12b is a region where the level difference D is less than or equal to the predetermined level difference D_{d}. The at least one preset film layer 12′ includes an insulating layer. The insulating layer in the first region 12a can be removed by patterning. The patterning may include a patterning process, which may include, exemplarily, the steps of coating photoresist, exposing, developing, etching, and stripping photoresist.

The substrate 10 may be a flexible substrate or a rigid substrate. The material of the flexible substrate may include polyimide, and the material of the rigid substrate may include glass.

In this embodiment, the insulating layer includes a passivation layer PVX.

This step S1 may include steps S11 to S13.

In step S11, as shown in FIG. 6, a switch transistor region and a drive transistor region on the substrate 10 respectively form in sequence: a bottom gate 121, a gate insulating layer 122, an active layer 123, an interlayer dielectric layer ILD, a source 124a (drain 124b), and a passivation layer PVX. In other words, the switch transistor X1 and the drive transistor X2 may be manufactured simultaneously.

Rows of scanning signal lines may be formed while the bottom gate 121 is formed. Columns of data signal lines and columns of power signal lines may be respectively formed while the source 124a (drain 124b) is formed. In other words, the rows of scanning signal lines may be disposed on the same layer as the bottom gate 121. The columns of data signal lines and the columns of power signal lines may be disposed on the same layer as the source 124a and the drain 124b.

In step S12, referring to FIG. 7, the passivation layer PVX in the first region 12a is removed.

The predetermined level difference D_{d} may be a predetermined proportion of the maximum predetermined level difference Dₘₐₓ, for example, 30%, 40%, 50%, 60%, 70%, or 80%. That is, the passivation layer PVX in the region where the level difference D exceeds 30%, 40%, 50%, 60%, 70%, or 80% of the maximum predetermined level difference Dₘₐₓ is removed.

The first region 12a may include at least regions where the source 124a and the drain 124b of the transistor are disposed.

In this step S12, the patterning of the passivation layer PVX may be completed by dry etching or wet etching. The mask plate in the dry etching or wet etching process may be a patterned photoresist.

In some embodiments, in step S12, part of the thickness of the passivation layer PVX in the first region 12a may also be removed, that is, thinning the passivation layer PVX in the first region 12a.

In step S13, referring to FIG. 3, through holes respectively exposing the drain 124b of the switch transistor X1 and the bottom gate 121 of the drive transistor X2 are prepared. The two through holes are filled with a conductive material (such as metal material). A metal layer is formed on the remaining passivation layer PVX, and then patterned to form a metal interconnection layer 125b. The metal material in the through hole forms a conductive plug 125a.

In turn, referring to step S2 in FIG. 5 and FIG. 3, a planarization layer PLN is formed on the at least one film layer 12, and a light-emitting structure 11 is formed on the planarization layer PLN.

Optionally, the planarization layer PLN may be formed by a coating method.

Optionally, with respect to a first electrodes 11a in at least one light-emitting structure 11, an entire surface of a first electrode material layer may be first formed by a deposition method, and then at least one first electrode block is formed by dry etching or wet etching. The pixel definition layer PDL may be formed by a coating method. The light-emitting structure block 11b may be formed by an evaporation method or an inkjet printing method. With respect to a second electrode 11c, an entire surface of a second electrode material layer may be formed by a deposition method.

Since the global level difference of the at least one film layer 12 is less than the global level difference of the at least one preset film layer 12′, the planarization effect of the planarization layer PLN can be improved, thereby improving the thickness uniformity of the light-emitting structure blocks 11b and improving the brightness uniformity.

For the switch transistor X1 and the drive transistor X2 with a top gate structure, in step S11, the switch transistor region and the drive transistor region on the substrate 10 respectively form in sequence: the active layer 123, the gate insulating layer 122, a top gate, the interlayer dielectric layer ILD, the source 124a (drain 124b), and the passivation layer PVX. For the subsequent steps, reference may be made to the steps of the above embodiments, which will not be repeated in this embodiment.

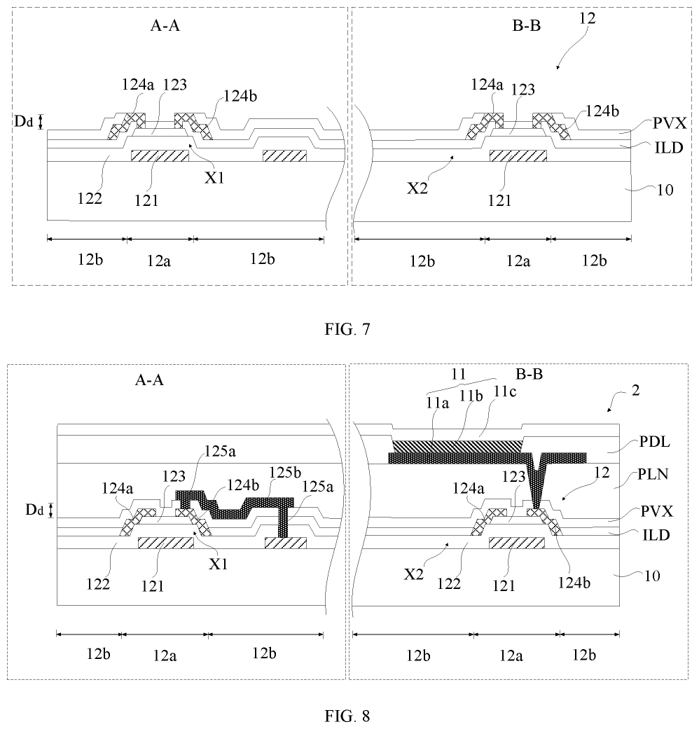

FIG. 8 is a schematic sectional structure diagram of another OLED panel according to an embodiment of the present disclosure. Referring to FIG. 8, an OLED panel 2 in this embodiment is substantially the same as the OLED panel 1 in FIGS. 1 to 4. The difference lies in that among the at least one film layer 12, the interlayer dielectric layer ILD in the first region 12a is removed.

Accordingly, for the manufacturing method, the difference lies in that in step S11, after the gate insulating layer ILD is formed, the interlayer dielectric layer ILD in the first region 12a is removed to expose a source region and a drain region (the source region may be regarded as a region where the source is disposed, and the drain region may be regarded as the location where the drain is disposed); then, sources 124a and 124b are correspondingly formed on the source region and the drain region. In step S12, the passivation layer PVX in the first region 12a is no longer removed.

In some embodiments, part of the thickness of the interlayer dielectric layer ILD in the first region 12a may also be removed. That is, the interlayer dielectric layer ILD in the first region 12a may be thinned.

Correspondingly, for the manufacturing method, the difference lies in that, in step S11, after the gate insulating layer ILD is formed, the interlayer dielectric layer ILD in the first region 12a is thinned, and through holes exposing the source region and the drain region are formed in the thinned interlayer dielectric layer ILD; then the through holes are filled with a conductive material (such as metal material) and the sources 124a and 124b are formed on the thinned interlayer dielectric layer ILD. In step S12, the passivation layer PVX in the first region 12a is no longer removed.

The solution of the embodiment shown in FIG. 8 may also be combined with the solution of the embodiment shown in FIGS. 1 to 7. That is, the interlayer dielectric layer ILD and the passivation layer PVX in the first region 12a are removed at the same time.

In some embodiments, part of the thickness of the interlayer dielectric layer ILD and the passivation layer PVX in the first region 12a may also be removed at the same time. That is, the interlayer dielectric layer ILD and the passivation layer PVX in the first region 12a may be thinned at the same time.

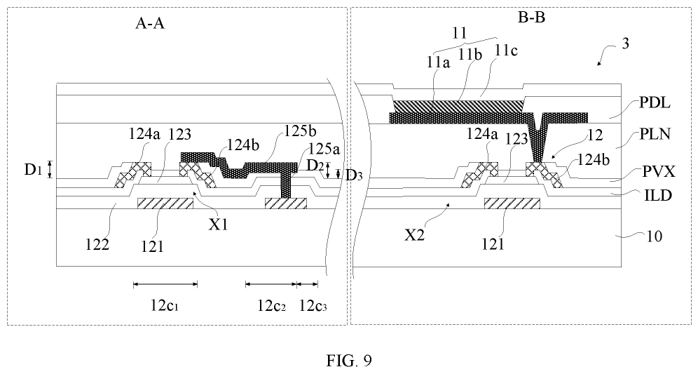

FIG. 9 is a schematic sectional structure diagram of another OLED panel according to an embodiment of the present disclosure. Referring to FIG. 9, an OLED panel 3 in this embodiment is substantially the same as the OLED panel 1 in FIGS. 1 to 4. The difference lies in that the first region includes a first sub-region 12c₁, and the second region includes a second sub-region 12c₂ and the third sub-region 12c₃; wherein the first sub-region 12c₁ is a region where the level difference D is greater than a first predetermined level difference D₁, the second sub-region 12c₂ is a region where the level difference D is greater than a second predetermined level difference D₂ and less than or equal to the first predetermined level difference D₁, and the third sub-region 12c₃ is a region where the level difference D is greater than a third predetermined level difference D₃ and less than or equal to the second predetermined level difference D₂, wherein the first predetermined level difference D₁, the second predetermined level difference D₂, and the third predetermined level difference D₃ gradually decrease; and the passivation layer PVX in the first sub-region 12c₁ is completely removed during patterning, and part of the thickness of the passivation layer PVX in the second sub-region 12c₂ and the third sub-region 12c₃ is removed during patterning and the removed thickness gradually decreases.

Correspondingly, for the manufacturing method, in step S12, the passivation layer PVX is dry-etched with a semi-transparent mask plate. The semi-transparent mask plate can be shielded by metal plating. The semi-transparent mask plate has a plurality of openings. The opening corresponding to the first sub-region 12c₁ is the largest, such that the photoresist exposure of the first sub-region 12c₁ is the largest, and the entire thickness of the passivation layer PVX in the first sub-region 12c₁ is completely removed. The opening corresponding to the second sub-region 12c₂ is larger than the opening corresponding to the third sub-region 12c₃, such that the photoresist exposure of the second sub-region 12c₂ is greater than the photoresist exposure of the third sub-region 12c₃, and the etching amount of the passivation layer PVX in the second sub-region 12c₂ is greater than the etching amount of the passivation layer PVX in the third sub-region 12c₃.

In some embodiments, the first region includes a first sub-region, a second sub-region, . . . , an N^{th} sub-region, and the second region includes an (N+1)^{th} sub-region, an (N+2)^{th} sub-region, . . . , the (N+M^{th} sub-region, N+M≥3; wherein the first sub-region is a region where a level difference is greater than a first predetermined level difference, the second sub-region is a region where the level difference is greater than a second predetermined level difference and less than or equal to the first predetermined level difference, the third sub-region is a region where the level difference is greater than the third predetermined level difference and less than or equal to the second predetermined level difference, . . . , the (N+M)^{th} sub-region is a region where the level difference is greater than an N^{th} predetermined level difference and less than or equal to an (N−1)^{th} predetermined level difference, wherein the first predetermined level difference, the second predetermined level difference, . . . , the N^{th} predetermined level difference gradually decrease; the passivation layer PVX in the first sub-region is completely removed during patterning, and part of the thickness of the passivation layer PVX in the second sub-region, the third sub-region, . . . , the (N+M)^{th} sub-region is removed during patterning and the removed thickness gradually decreases.

Correspondingly, for the manufacturing method, in openings of the semi-transparent mask plate, the opening corresponding to the first sub-region is larger than the opening corresponding to the second sub-region, and the opening corresponding to the second sub-region is larger than the opening corresponding to the third sub-region, . . . , the opening corresponding to the (N+M−1)^{th} sub-region is larger than the opening corresponding to the (N+M)^{th} sub-region, such that the photoresist exposure of the first sub-region, the second sub-region, . . . , the (N+M)^{th} sub-region gradually decreases.

Alternatively, another semi-transparent mask plate has mask regions corresponding to the sub-regions. The light transmittance of the mask region corresponding to the first sub-region is greater than the light transmittance of the mask region corresponding to the second sub-region, the light transmittance of the mask region corresponding to the second sub-region is greater than the light transmittance of the mask region corresponding to the third sub-region, . . . , the light transmittance of the mask region corresponding to the (N+M−1)^{th} sub-region is greater than the light transmittance of the mask region corresponding to the (N+M)^{th} sub-region, such that the photoresist exposure in the first sub-region, the second sub-region, . . . , the (N+M)^{th} sub-region gradually decreases.

The solution in this embodiment may also be combined with the solution of the embodiment shown in FIG. 8. That is, the removal thickness of the interlayer dielectric layer ILD in different regions is different.

Based on the above OLED panels 1, 2, and 3, an embodiment of the present disclosure provides another display device including any one of the above OLED panels 1, 2, and 3. The display device may be any product or component with a display function, such as an electronic paper, a mobile phone, a tablet computer, a television, a notebook computer, a digital photo frame, a navigator, and the like.

It should be pointed out that in the drawings, the sizes of layers and regions may be exaggerated for clarity of illustration. It will also be understood that when an element or layer is referred to as being “on” another element or layer, it may be directly on the other element or an intervening layer may be present. In addition, it can be understood that when an element or layer is referred to as being “under” another element or layer, it may be directly under the other element, or more than one intervening layer or element may be present. In addition, it can also be understood that when a layer or element is referred to as being “between” two layers or two elements, it may be the only layer between the two layers or two elements, or more than one intervening layer or component may also be present. Similar reference numerals indicate similar elements throughout.

In the present disclosure, the terms “first”, “second”, . . . , “(N+M)^{th}” are only used for descriptive purposes, and cannot be understood as indicating or implying relative importance. The term “at least one” refers to one, two or more than two, unless specifically defined otherwise.

The term “and/or” in the present disclosure is merely an association relationship describing associated objects, indicating that there may be three types of relationships. For example, A and/or B may mean that A exists alone, both A and B exist, and B exists alone. In addition, the character “/” used herein generally indicates that the associated objects before and after are in an “or” relationship.

After considering the description and practicing the present disclosure, those skilled in the art will easily think of other embodiments of the present disclosure. The present disclosure is intended to cover any variations, uses, or adaptive changes of the present disclosure. These variations, uses, or adaptive changes follow general principles of the present disclosure and include common knowledge or customary technical means in the technical field that are not disclosed in the present disclosure. The description and the embodiments are only regarded as exemplary, and the true scope and spirit of the present disclosure are defined in the appended claims.

It should be understood that the present disclosure is not limited to the precise structure that has been described above and shown in the drawings, and various modifications and changes can be made without departing from its scope. The scope of the present disclosure is only limited by the appended claims.

1. An organic light-emitting diode (OLED) panel, comprising: a substrate, and a light-emitting structure disposed on the substrate; wherein
at least one film layer and a planarization layer disposed on the at least one film layer are disposed between the substrate and the light-emitting structure, the at least one film layer comprising a transistor;
the OLED panel comprises a first region and a second region, wherein a source and a drain of the transistor are disposed in the first region; and
wherein the at least one film layer comprises an insulating layer, wherein a thickness of the insulating layer in the first region is less than a thickness of the insulating layer in the second region.

2. The OLED panel according to claim 1, wherein the insulating layer comprises an interlayer dielectric layer and/or a passivation layer.

3. The OLED panel according to claim 2, wherein along a direction facing away from the substrate, the at least one film layer sequentially comprises: a bottom gate, a gate insulating layer, an active layer, the interlayer dielectric layer, the source, the drain, and the passivation layer.

4. The OLED panel according to claim 3, wherein the interlayer dielectric layer and/or the passivation layer is disposed only in the second region.

5. The OLED panel according to claim 3, wherein a thickness of the interlayer dielectric layer in the first region is less than a thickness of the interlayer dielectric layer in the second region, and/or a thickness of the passivation layer in the first region is less than a thickness of the passivation layer in the second region.

6. The OLED panel according to claim 2, wherein along a direction facing away from the substrate, the at least one film layer sequentially comprises: an active layer, a gate insulating layer, a top gate, the interlayer dielectric layer, the source, the drain, and the passivation layer.

7. The OLED panel according to claim 6, wherein the interlayer dielectric layer and/or the passivation layer is disposed only in the second region.

8. The OLED panel according to claim 6, wherein a thickness of the interlayer dielectric layer in the first region is less than a thickness of the interlayer dielectric layer in the second region, and/or a thickness of the passivation layer in the first region is less than a thickness of the passivation layer in the second region.

9. The OLED panel according to claim 1, wherein the at least one film layer comprises at least two transistors, and the first region further comprises a region where a connecting line between two of the at least two transistors is disposed.

10. The OLED panel according to claim 1, wherein the at least one film layer comprises pixel drive circuits configured to drive the light-emitting structure to emit light, and/or the at least one film layer comprises connecting lines connecting the pixel drive circuits.

11. The OLED panel according to claim 1, wherein the at least one film layer comprises a light shielding layer.

12. The OLED panel according to claim 1, wherein the first region comprises N sub-regions, the second region comprises M sub-regions, N+M≥3, and the thickness of the insulating layer in any two of the N+M sub-regions is different.

13. The OLED panel according to claim 1, wherein along a direction facing away from the substrate, the at least one film layer sequentially comprises: a bottom gate, a gate insulating layer, an active layer, the interlayer dielectric layer, the source, the drain, and the passivation layer;
the at least one film layer comprises at least two transistors, and the first region further comprises a region where a connecting line between two of the at least two transistors is disposed;
the at least one film layer comprises pixel drive circuits configured to drive the light-emitting structure to emit light, and/or the at least one film layer comprises connecting lines connecting the pixel drive circuits;
the at least one film layer comprises a light shielding layer; and
the first region comprises N sub-regions, the second region comprises M sub-regions, N+M≥3, and the thickness of the insulating layer in any two of the N+M sub-regions is different.

14. A display device, comprising an organic light-emitting diode (OLED) panel comprising: a substrate, and a light-emitting structure disposed on the substrate; wherein
at least one film layer and a planarization layer disposed on the at least one film layer are disposed between the substrate and the light-emitting structure, the at least one film layer comprising a transistor;
the OLED panel comprises a first region and a second region, wherein a source and a drain of the transistor are disposed in the first region; and
wherein the at least one film layer comprises an insulating layer, wherein a thickness of the insulating layer in the first region is less than a thickness of the insulating layer in the second region.

15. A method for manufacturing an organic light-emitting diode (OLED) panel, comprising:
providing a substrate;
forming at least one film layer on the substrate, wherein the at least one film layer comprises a transistor, the OLED panel comprises a first region and a second region, a source and a drain of the transistor being disposed in the first region, and the at least one film layer comprises an insulating layer, wherein a thickness of the insulating layer in the first region is less than a thickness of the insulating layer in the second region;
forming a planarization layer on the at least one film layer; and
forming a light-emitting structure on the planarization layer.

16. The method according to claim 15, wherein
the insulating layer comprises an interlayer dielectric layer; and
forming the at least one film layer on the substrate comprises:
sequentially forming a bottom gate, a gate insulating layer, an active layer, and the interlayer dielectric layer on the substrate;
removing or thinning the interlayer dielectric layer in the first region, and forming, in the interlayer dielectric layer, through holes exposing a source region and a drain region; and
filling the through holes with a conductive material, and forming a source and a drain on the interlayer dielectric layer.

17. The method according to claim 15, wherein
the insulating layer comprises an interlayer dielectric layer; and
forming the at least one film layer on the substrate comprises:
sequentially forming an active layer, a gate insulating layer, a top gate, and the interlayer dielectric layer on the substrate;
removing or thinning the interlayer dielectric layer in the first region, and forming, in the interlayer dielectric layer and the gate insulating layer, through holes exposing a source region and a drain region; and
filling the through holes with a conductive material, and forming a source and a drain on the interlayer dielectric layer.

18. The method according to claim 16, wherein
the insulating layer further comprises a passivation layer; and
forming the at least one film layer on the substrate further comprises:
forming the passivation layer on the source, the drain, and the interlayer dielectric layer; and
removing or thinning the passivation layer in the first region.

19. The method according to claim 15, wherein
the insulating layer comprises a passivation layer; and
forming the at least one film layer on the substrate comprises:
sequentially forming a bottom gate, a gate insulating layer, an active layer, and an interlayer dielectric layer on the substrate;
forming, in the interlayer dielectric layer, through holes exposing a source region and a drain region;
filling the through holes with a conductive material, and forming a source and a drain on the interlayer dielectric layer;
forming the passivation layer on the source, the drain, and the interlayer dielectric layer; and
removing or thinning the passivation layer in the first region;
or
forming the at least one film layer on the substrate comprises:
sequentially forming an active layer, a gate insulating layer, a top gate, and an interlayer dielectric layer on the substrate;
forming, in the interlayer dielectric layer and the gate insulating layer, through holes exposing a source region and a drain region;
filling the through holes with a conductive material, and forming a source and a drain on the interlayer dielectric layer;
forming the passivation layer on the source, the drain, and the interlayer dielectric layer; and
removing or thinning the passivation layer in the first region.

20. The method according to claim 15, wherein
the first region comprises: a first sub-region, and sub-regions from a second sub-region to an Nth sub-region, and the second region comprises: an (N+1)^{th} sub-region, and sub-regions from an (N+2)^{th} sub-region to an (N+M)^{th} sub-region, N+M≥3; wherein the first sub-region is a region where a level difference is greater than a first predetermined level difference, the second sub-region is a region where the level difference is greater than a second predetermined level difference and less than or equal to the first predetermined level difference, the third sub-region is a region where the level difference is greater than a third predetermined level difference and less than or equal to the second predetermined level difference, and the (N+M)^{th} sub-region is a region where the level difference is greater than an (N+M)^{th} predetermined level difference and less than or equal to an (N+M−1)^{th} predetermined level difference, wherein the first predetermined level difference, and the second predetermined level difference to the (N+M)^{th} predetermined level difference gradually decrease; and
forming the at least one film layer on the substrate comprises:
processing the insulating layer with a semi-transparent mask plate to completely remove the insulating layer in the first sub-region, and remove part of the thickness of the insulating layer in the second sub-region, the third sub-region to the (N+M)^{th} sub-region, wherein the thickness of the insulating layer removed from the second sub-region, the third sub-region to the (N+M)^{th} sub-region gradually decreases.
